(19) United States
(12) Patent Application Publication
(10) Pub. No.: US 2026/0096423 A1
(43) Pub. Date: Apr. 2, 2026

(54) METHODS FOR FORMING LOW-RESISTIVITY INTERCONNECT STRUCTURES COMPRISING RUTHENIUM

(71) Applicant: Tokyo Electron Limited, Tokyo (JP)

(72) Inventors: Tek Po Rinus Lee, Albany, NY (US); Kenichi Imakita, Albany, NY (US); Joshua Mayersky, Albany, NY (US)

(21) Appl. No.: 18/903,784

(22) Filed: Oct. 1, 2024

(51) Int. Cl. H01L 23/532; H01L 21/768; H01L 23/535

(52) U.S. Cl. CPC H10W 20/4432; H10W 20/062; H10W 20/0698; H10W 20/083; H10W 20/20

(57) ABSTRACT

Various embodiments of interconnect structures and methods of forming interconnect structures used in an integrated circuit (IC) device are provided in the present disclosure. More specifically, techniques are provided for forming low-resistivity interconnect structures including a multilayer interconnect film stack comprising a first conductive film formed beneath and in contact with a second conductive film. The presence of the first conductive film within the multilayer interconnect film stack decreases the resistivity of the second conductive film when the second conductive film is deposited onto the first conductive film to provide a low-resistivity interconnect structure.

### TECHNICAL FIELD

The present disclosure relates to the integrated circuit (IC) devices. In particular, it provides improved interconnect structures for IC devices.

### BACKGROUND

Copper (Cu) has been used as the interconnect metal of choice since the early 2000s due to its low bulk resistivity (ρ₀=1.7 μΩ cm) and resistance to electromigration. However, continuous scaling of IC devices has resulted in significant shrinkage in the dimensions of local interconnects, which has led to a substantial increase in the total resistivity of Cu and total resistance of the Cu metal lines. The total resistivity of Cu interconnects rapidly increases as the interconnect linewidth decreases below the electron mean free path (EMFP) in bulk Cu (λ=39 nm), due to increased electron scattering at the surfaces and grain boundaries. For example, when the linewidth of a Cu interconnect is reduced to 10 nm, electron scattering causes about a ten-fold increase in line resistivity value, compared to the bulk resistivity (ρ₀=1.7 μΩ cm) of Cu metal. The increased line resistivity increases both power consumption and speed delay, which limits IC device performance and hampers scaling.

The increase in total resistivity of metallization layers at smaller dimensions (≤10 nm) is a major challenge for the semiconductor industry, resulting in on-going research efforts that focus on improving current metallization schemes, as well as exploring potential replacement materials for Cu.

Low-resistivity metals, such as ruthenium (Ru), molybdenum (Mo), tungsten (W), cobalt (Co), etc., have been investigated for use as barrier layers in Cu interconnects, as well as potential replacements for Cu interconnects. Ru is an attractive barrier material, due to its resistance to electromigration and diffusion into surrounding low-k dielectric materials. Ru has also been proposed as an effective replacement for Cu in local interconnects, transistors and capacitor electrodes, due to its low bulk resistivity (ρ₀=7.0 μΩ cm), high work function (4.7 eV), and excellent thermal and chemical stability. Because Ru has a much shorter electron mean-free-path (λ=6.58 nm) than Cu (λ=39 nm), Ru also demonstrates a lower total resistivity (e.g., ρ=4 to 20 μΩ cm) than Cu at smaller dimensions (e.g., ≤10 nm), due to the reduced electron scattering at the surfaces and grain boundaries.

Ru films have been fabricated using a wide variety of deposition techniques, such as electroplating, chemical vapor deposition (CVD), physical vapor deposition (PVD) and atomic layer deposition (ALD). The resistivity of the Ru film depends not only on the deposition process and chemistry used to form the Ru film, but also on the grain size, crystalline orientation and surface roughness of the deposited film. For example, it has been found that larger, more uniform Ru grains decrease the nanoscale resistivity of the deposited Ru film by decreasing electron scattering at the grain boundaries. Therefore, techniques that increase the grain size and improve the crystallinity of the Ru film are desirable.

### SUMMARY

The present disclosure provides various embodiments of interconnect structures and methods of forming interconnect structures used in an integrated circuit (IC) device. More specifically, the present disclosure discloses novel methods and techniques for forming low-resistivity interconnect structures. The interconnect structures disclosed herein may generally include a multilayer interconnect film stack comprising a first conductive film formed beneath and in contact with a second conductive film. The presence of the first conductive film within the multilayer interconnect film stack decreases the resistivity of the second conductive film when the second conductive film is deposited onto the first conductive film to provide a low-resistivity interconnect structure.

According to one embodiment, an integrated circuit (IC) device comprising at least one interconnect is provided. The at least one interconnect may generally include a multilayer interconnect film stack comprising a first conductive film formed beneath and in contact with a second conductive film, wherein the first conductive film comprises niobium (Nb), wherein the second conductive film comprises ruthenium (Ru), and wherein the first conductive film decreases a resistivity of the second conductive film by increasing a grain size and/or improving a crystalline orientation of the second conductive film. In some embodiments, the first conductive film may increase the grain size and/or improve the crystalline orientation of the second conductive film during a deposition process used to deposit the second conductive film onto the first conductive film to form the multilayer interconnect film stack.

The first conductive film and the second conductive film may each include a transition metal, a transition metal oxide or a transition metal nitride. In some embodiments, for example, the first conductive film may be a niobium (Nb) film, a niobium oxide (NbxOy) film or a niobium nitride (NbN) film, and the second conductive film may be a ruthenium (Ru) film, a ruthenium oxide (RuOx) film or a ruthenium nitride (RuNx) film. In one example embodiment, the first conductive film may be a niobium (Nb) film and the second conductive film may be a ruthenium (Ru) film. In such embodiments, the niobium (Nb) film may decrease a resistivity of the ruthenium (Ru) film by approximately 10-15% compared to a resistivity of a ruthenium (Ru) film of the same thickness without an underlying niobium (Nb) film.

In some embodiments the first conductive film may have a lower electrical conductivity and higher resistivity than the second conductive film. To improve the conductivity of the at least one interconnect, the thickness of the second conductive film may be greater than the thickness of the first conductive film. For example, when a ruthenium (Ru) film is used to implement the second conductive film, the thickness of the Ru film may range between 20 nm and 100 nm. In some embodiments, the Ru film thickness may range between 25 nm and 45 nm, or more specifically, between 30 nm and 35 nm. When a niobium (Nb) film is used to implement the first conductive film, the thickness of the Nb film may range between 1 nm and 10 nm. In some embodiments, the Nb film thickness may range between 2 nm and 8 nm, or more specifically, between 3 nm and 6 nm.

In some embodiments, the multilayer interconnect film stack may further include a second ruthenium (Ru) film formed below and in contact with the niobium (Nb) film. In such embodiments, a thickness of the ruthenium (Ru) film may range between 5 nm and 50 nm, a thickness of the niobium (Nb) film may range between 1 nm and 10 nm, and a thickness of the second ruthenium (Ru) film may range between 5 nm and 50 nm.

According to another embodiment, a method is provided herein to form interconnects in an integrated circuit (IC) device. In general, the method may begin by forming a multilayer interconnect film stack on an underlying IC structure. The multilayer interconnect film stack may be formed by performing a first deposition process to deposit a first conductive film above the underlying IC structure and subsequently performing a second deposition process to deposit a second conductive film above and in contact with the first conductive film. The first conductive film may generally comprise niobium (Nb). For example, first conductive film may be a niobium (Nb) film, a niobium oxide (NbₓO_{y}) film or a niobium nitride (NbN) film. The second conductive film may generally comprise ruthenium (Ru). For example, second conductive film may be a ruthenium (Ru) film, a ruthenium oxide (RuOₓ) film or a ruthenium nitride (RuNₓ) film. When the second conductive film is deposited onto the first conductive film during the second deposition process, the presence of the first conductive film may increase a grain size and/or improve a crystalline orientation of the second conductive film to decrease a resistivity of the overlying second conductive film.

In some embodiments, the first conductive film may be a niobium (Nb) film having a thickness ranging between 1 nm and 10 nm, and the second conductive film may be a ruthenium (Ru) film having a thickness ranging between 20 nm and 100 nm. In such embodiments, the niobium (Nb) film may decrease a resistivity of the ruthenium (Ru) film by approximately 10-15% compared to a resistivity of a ruthenium (Ru) film of the same thickness without an underlying niobium (Nb) film.

In some embodiments, the said forming multilayer interconnect film stack may further comprise performing a deposition process to deposit a second ruthenium (Ru) film on the underlying IC structure before the first deposition process is performed to deposit the niobium (Nb) film on the second ruthenium (Ru) film. In such embodiments a thickness of the ruthenium (Ru) film ranges between 5 nm and 50 nm, a thickness of the niobium (Nb) film may range between 1 nm and 10 nm, and a thickness of the second ruthenium (Ru) film may range between 5 nm and 50 nm.

After the multilayer interconnect film stack is formed, the method may further include etching the multilayer interconnect film stack to form a plurality of interconnects, each comprising the second conductive film formed above and in contact with the first conductive film, and depositing a dielectric layer on and between the plurality of interconnects. In some embodiments, the method may further include etching the dielectric layer to form at least one opening above at least one interconnect of the plurality of interconnects. The at least one opening may extend from an upper surface of the dielectric layer to an upper surface of the second conductive film included within the at least one interconnect.

In some embodiments, the method may further include: (a) performing a third deposition process to deposit a first conductive material on the upper surface of the dielectric layer and within the at least one opening, (b) planarizing the first conductive material to remove the first conductive material from the upper surface of the dielectric layer and provide a planarized surface that exposes the first conductive material deposited within the at least one opening, and (c) performing one or more additional deposition processes to deposit one or more conductive layers on the planarized surface.

In some embodiments, the method may further include: (d) performing a fourth deposition process to deposit a niobium (Nb) layer on the planarized surface, and (e) performing a fifth deposition process to deposit a ruthenium (Ru) layer on the niobium (Nb) layer. The niobium (Nb) layer may be deposited to a thickness ranging between 1 nm and 10 nm, and the ruthenium (Ru) layer may be deposited to a thickness ranging between 10 nm and 100 nm. In such embodiments, the niobium (Nb) layer may increase a grain size and improve a crystalline orientation of the ruthenium (Ru) layer during the fifth deposition process to decrease a resistivity of the ruthenium (Ru) layer.

In other embodiments, the method may further include: (d) performing a fourth deposition process to deposit a first ruthenium (Ru) layer on the planarized surface, (e) performing a fifth deposition process to deposit a niobium (Nb) layer on the first ruthenium (Ru) layer, and (f) performing a sixth deposition process to deposit a second ruthenium (Ru) layer on the niobium (Nb) layer. The first ruthenium (Ru) layer may be deposited to a thickness ranging between 20 nm and 50 nm, the niobium (Nb) layer may be deposited to a thickness ranging between 1 nm and 10 nm, and the second ruthenium (Ru) layer may be deposited to a thickness ranging between 20 nm and 50 nm. In such embodiments, the niobium (Nb) layer may increase a grain size and improve a crystalline orientation of the second ruthenium (Ru) layer during the sixth deposition process to decrease a resistivity of the second ruthenium (Ru) layer.

As noted above and described further herein, the present disclosure provides various embodiments of interconnect structures and methods of forming interconnect structures in an IC device. Of course, the order of discussion of the different steps as described herein has been presented for the sake of clarity. In general, these steps can be performed in any suitable order. Additionally, although each of the different features, techniques, configurations, etc., herein may be discussed in different places of this disclosure, it is intended that each of the concepts can be executed independently of each other or in combination with each other. Accordingly, the present invention can be embodied and viewed in many different ways.

Note that this Summary section does not specify every embodiment and/or incrementally novel aspect of the present disclosure or claimed inventions. Instead, the summary only provides a preliminary discussion of different embodiments and corresponding points of novelty over conventional techniques. For additional details and/or possible perspectives of the invention and embodiments, the reader is directed to the Detailed Description section and corresponding figures of the present disclosure as further discussed below.

### BRIEF DESCRIPTION OF THE DRAWINGS

A more complete understanding of the present inventions and advantages thereof may be acquired by referring to the following description taken in conjunction with the accompanying drawings, in which like reference numbers indicate like features. It is to be noted, however, that the accompanying drawings illustrate only exemplary embodiments of the disclosed concepts and are therefore not to be considered limiting of the scope, for the disclosed concepts may admit to other equally effective embodiments.

FIG. 1A is a cross-sectional view of a portion of an IC device including one embodiment of a low-resistivity interconnect structure formed in accordance with the present disclosure.

FIG. 1B is a cross-sectional view of a portion of an IC device including another embodiment of a low-resistivity interconnect structure formed in accordance with the present disclosure.

FIG. 2 is a graph illustrating the film resistivity (expressed in u (cm) vs. ruthenium film thickness (expressed in nm) for a multilayer interconnect film stack comprising a ruthenium film formed above various transition metal film layers.

FIG. 3 is a graph illustrating the film resistivity (expressed in μΩ cm) vs. ruthenium film thickness (expressed in nm) for a multilayer interconnect film stack comprising a 30 nm ruthenium film formed above a niobium (Nb) film of various film thicknesses.

FIG. 4 is a flowchart diagram illustrating one embodiment of a method that utilizes the techniques described herein to form a low-resistivity interconnect structure.

FIGS. 5A-5G are cross-sectional views of a portion of an IC device, illustrating an example process flow that utilizes the techniques described herein to form a low-resistivity interconnect structure.

FIG. 6 is a cross-sectional view of a portion of an IC device illustrating another embodiment of a low-resistivity interconnect structure formed in accordance with the present disclosure.

### DETAILED DESCRIPTION

The present disclosure provides various embodiments of interconnect structures and methods of forming interconnect structures used in an integrated circuit (IC) device. More specifically, the present disclosure discloses novel methods and techniques for forming low-resistivity interconnect structures. The interconnect structures disclosed herein may generally include a multilayer interconnect film stack comprising a first conductive film formed beneath and in contact with a second conductive film. The presence of the first conductive film within the multilayer interconnect film stack decreases the resistivity of the second conductive film when the second conductive film is deposited onto the first conductive film to provide a low-resistivity interconnect structure.

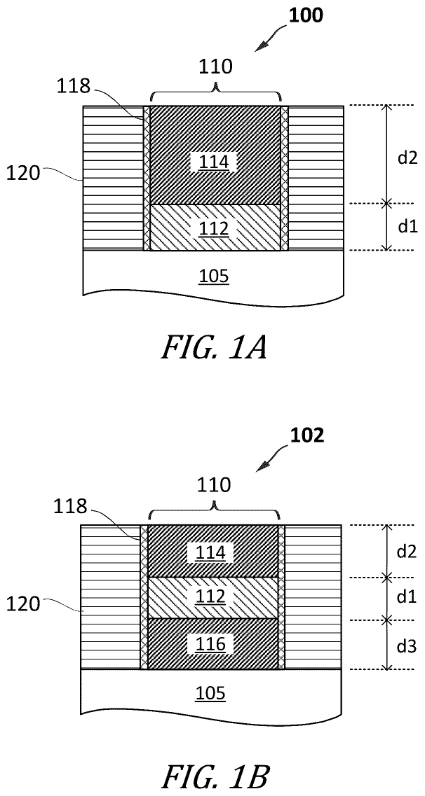

FIG. 1A is a cross-sectional view of a portion of an IC device including at least one interconnect 100 that provides an electrical pathway between an underlying IC structure 105 and an overlying IC structure (not shown). The at least one interconnect 100, which may be a via, contact or metal line, includes a multilayer interconnect film stack 110 surrounded by a dielectric layer 120. The dielectric layer 120 may include any suitable dielectric material, such as an interlayer dielectric (ILD) layer material or another low-k dielectric material. In some embodiments, a liner material 118 may be formed on sidewalls of the multilayer interconnect film stack 110 to prevent diffusion into the dielectric layer 120. It is recognized, however, that the liner material 118 is an optional feature of the embodiments disclosed herein and may be omitted.

In the embodiment shown in FIG. 1A, the multilayer interconnect film stack 110 includes a first conductive film 112 formed beneath and in contact with a second conductive film 114. A wide variety of deposition processes, such as physical vapor deposition (PVD), chemical vapor deposition (CVD) and atomic layer deposition (ALD), may be used to form the first conductive film 112 and the second conductive film 114. When the second conductive film 114 is deposited onto the first conductive film 112, the presence of the first conductive film 112 increases a grain size and improves a crystalline orientation of the second conductive film 114 to decrease the resistivity of the first conductive film 112 and provide a low-resistivity interconnect structure 100.

The first conductive film 112 and the second conductive film 114 may each include a wide variety of electrically conductive materials, including metals, metal oxides and metal nitrides. In some embodiments, the electrically conductive material chosen for the first conductive film 112 may have a lower electrical conductivity and higher resistivity than the electrically conductive material chosen for the second conductive film 114. When current is applied to the at least one interconnect 100 in such embodiments, the majority of the current may flow through the (more conductive) second conductive film 114. To improve the electrical conductivity of the at least one interconnect 100, the thickness (d2) of the second conductive film 114 may be greater than the thickness (d1) of the first conductive film 112.

In some embodiments, the first conductive film 112 and the second conductive film 114 may each include a transition metal (e.g., ruthenium (Ru), tungsten (W), molybdenum (Mo), niobium (Nb), platinum (Pt), cobalt (Co), etc.), a transition metal oxide or a transition metal nitride. In some embodiments, the second conductive film 114 may comprise a first transition metal-containing material and the first conductive film 112 may comprise a second transition metal-containing material that decreases the resistivity of the second conductive film 114 when the second conductive film 114 is deposited onto the first conductive film 112.

In some embodiments, the second conductive film 114 may comprise ruthenium. For example, the second conductive film 114 may be a ruthenium (Ru) film, a ruthenium oxide (RuOₓ) film or a ruthenium nitride (RuNₓ) film. In some embodiments, the first conductive film 112 may comprise niobium (Nb). For example, the first conductive film 112 may be a niobium (Nb) film, a niobium oxide (NbₓO_{y}) film or a niobium nitride (NbN) film. In one example embodiment, the first conductive film 112 may be a niobium (Nb) film and the second conductive film 114 may be a ruthenium (Ru) film. Other examples of transition metal-containing materials that decrease the resistivity of a ruthenium (Ru) film are discussed in more detail below.

As noted above, the thickness (d2) of the second conductive film 114 may be greater than the thickness (d1) of the first conductive film 112 to improve the conductivity of the at least one interconnect 100. When a ruthenium (Ru) film is used to implement the second conductive film 114, the thickness (d2) of the Ru film may range between 20 nm and 100 nm. In some embodiments, the Ru film thickness may range between 25 nm and 45 nm, or more specifically, between 30 nm and 35 nm. When a niobium (Nb) film is used to implement the first conductive film 112, the thickness (d1) of the Nb film may range between 1 nm and 10 nm. In some embodiments, the Nb film thickness may range between 2 nm and 8 nm, or more specifically, between 3 nm and 6 nm.

As dimensions of local interconnects decrease into the nanoscale range, the resistivity of the metal film(s) used within the local interconnects tends to increase as electron scattering becomes more pronounced at surfaces and grain boundaries. For example, the total resistivity (ρₜₒₜₐₗ) of a square metal wire of thickness (d) can be approximated as:

$${ρ}_{total} = {ρ}_{0} + {ρ}_{0} λ ( \frac{3 ( 1 - p )}{4 d} ) + {ρ}_{0} λ ( \frac{3 R}{2 D ( 1 - R )} ) .$$

As shown in the equation above, the total resistivity (ρₜₒₜₐₗ) of a metal film depends on the bulk resistivity (ρ₀), electron mean free path (EMFP, A), thickness (d) and average grain size (D) of the metal, as well as the surface scattering parameter (p) and grain boundary scattering parameter (R). For example, the total resistivity (ρₜₒₜₐₗ) of a 30 nm Ru film, which has a bulk resistivity (ρ₀) of about 7.0μΩ cm and an EMFP (λ) of 6.58 nm, may range between about 4 μΩ cm and 20 μΩ cm, depending on the deposition process/parameters used to form the Ru film. In one example implementation, a 30 nm Ru film deposited via PVD may have a film resistivity of approximately 11.5μΩ cm.

As the thickness (d) of the metal film decreases, electron scattering at surfaces and grain boundaries becomes more prominent, leading to an increase in the total resistivity (ρₜₒₜₐₗ). Electron scattering depends not only the grain size (D), but also on the crystalline orientation of the metal film. For example, metal films with smaller grain size (D) and more random orientation exhibit greater electron scattering at surfaces and grain boundaries. Conversely, metal films with larger grain size (D) and more uniform orientation exhibit less electron scattering at surfaces and grain boundaries. Thus, for a given metal film of thickness (d), the total resistivity (ρₜₒₜₐₗ) of the metal film can be reduced by increasing the grain size (D) and/or improving the crystalline orientation of the metal film.

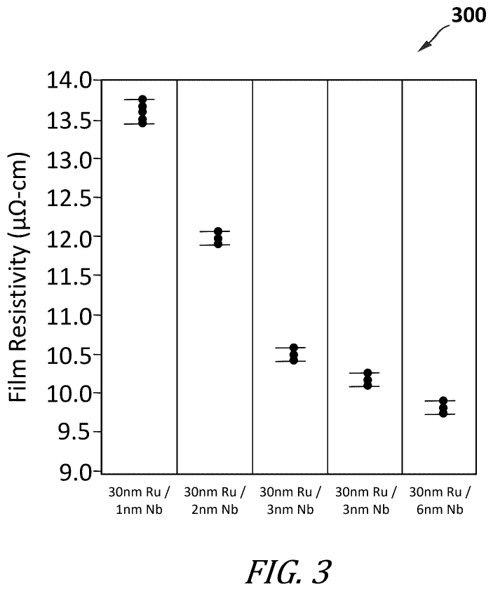

In the interconnect 100 structure shown in FIG. 1A, the first conductive film 112 decreases the resistivity of the second conductive film 114 by increasing the grain size (D) and/or improving the crystalline orientation of the second conductive film 114 when the second conductive film 114 is deposited onto the first conductive film 112. In some embodiments, a niobium (Nb) film formed beneath a Ru film may decrease the resistivity of the overlying ruthenium (Ru) film by approximately 10-15%, compared to the resistivity of an Ru film of the same thickness without an underlying Nb film. In one example, a 6 nm Nb film formed beneath a 30 nm Ru film may decrease the resistivity of the overlying Ru film from about 11.5μΩ cm to about 9.8μΩ cm, as shown in FIG. 3.

FIG. 1B illustrates another embodiment of an interconnect 102 including a multilayer interconnect film stack 110. The multilayer interconnect film stack 110 shown in FIG. 1B includes a first conductive film 112 formed beneath and in contact with a second conductive film 114, as described above in reference to FIG. 1A. The multilayer interconnect film stack 110 shown in FIG. 1B further includes a third conductive film 116, which is formed below and in contact with the first conductive film 112. The first conductive film 112, the second conductive film 114 and the third conductive film 116 may each include a transition metal (e.g., ruthenium (Ru), tungsten (W), molybdenum (Mo), niobium (Nb), platinum (Pt), cobalt (Co), etc.), a transition metal oxide or a transition metal nitride, as described above. In one example embodiment, the second conductive film 114 may be a ruthenium (Ru) film having a deposition thickness (d2) ranging between 5 nm and 50 nm, the first conductive film 112 may be a niobium (Nb) film having a deposition thickness (d1) ranging between 1 nm and 10 nm and the third conductive film 116 may be a second ruthenium (Ru) film having a deposition thickness (d3) ranging between 5 nm and 50 nm.

Experiments were conducted to determine optimum material compositions and thicknesses for the conductive film layers included within the multilayer interconnect film stack. In a first experiment, multilayer interconnect film stacks were formed by depositing ruthenium (Ru) films of different thickness (e.g., about 20-40 nm) onto various transition metal film layers (e.g., a titanium nitride (TiN) layer, a tantalum (Ta) layer, a tantalum nitride (TaN) layer, a niobium (Nb) layer and two separate titanium oxide (TOₓ) substrates). Once the multilayer interconnect structures were formed, the film resistivity of the overlying Ru film was measured to determine which of the transition metal film layers produced the greatest effect on Ru film resistivity.

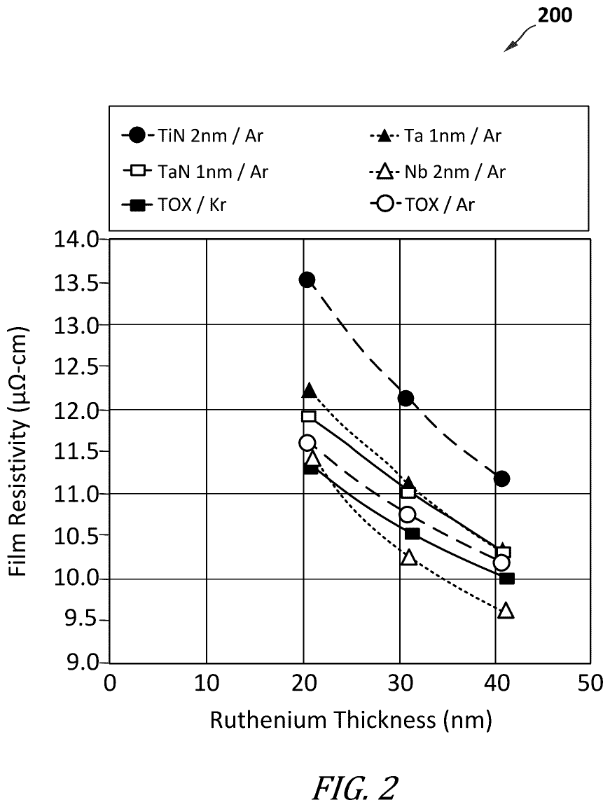

The graph 200 shown in FIG. 2 illustrates the film resistivity (expressed in μΩ cm) vs. Ru film thickness (expressed in nm) for multilayer interconnect film stacks comprising 20 nm, 30 nm and 40 nm Ru films formed on: (a) a 2 nm TiN layer, (b) a 1 nm Ta layer, (c) a 1 nm TaN layer, (d) a 2 nm Nb layer, (e) a first TOₓ substrate, and (f) a second TOₓ substrate. As shown in the graph 200, the film resistivity generally decreases with increasing Ru film thickness. However, the graph 200 further shows that the Ru/Nb film stacks provide the lowest film resistivity among the metals investigated, regardless of the Ru film thickness.

In a second experiment, multilayer interconnect film stacks were formed by depositing a 30 nm Ru film on Nb layers of various film thickness. Once the multilayer interconnect structures were formed, the film resistivity of the overlying Ru film was measured to determine an optimal thickness for the Nb film in the Ru/Nb film stack.

The graph 300 shown in FIG. 3 illustrates the film resistivity (expressed in un cm) vs. Ru film thickness (expressed in nm) for multilayer interconnect film stacks comprising 30 nm Ru films formed on: (a) a 1 nm Nb film, (b) a 2 nm Nb film, (c) a first 3 nm Nb film, (d) a second 3 nm Nb film, and (e) a 6 nm Nb film. The film resistivity of a 30 nm Ru film without an underlying Nb layer is approximately 11.5 μΩ cm. The film resistivity initially increases with the addition of a 1-2 nm Nb film beneath the 30 nm Ru film. The initial increased film resistivity may be attributed to increased scattering due to non-uniform film deposition. Beyond 2 nm, the film resistivity generally decreases with increasing Nb film thickness up until a certain point (e.g., about 10 nm), after which the film resistivity begins to increase. The increase in film resistivity for Nb film thicknesses beyond 10 nm can be attributed to the higher resistivity of the Nb film (e.g., >30 μΩ cm for Nb film thicknesses 10 nm or more).

The graphs shown in FIGS. 2-3 show that insertion of a relatively thin Nb film (e.g., about 1-10 nm) within an Ru/Nb film stack reduces the film resistivity of the overlying Ru film. While not being constrained to theory, it is believed that when an Ru film is deposited onto an underlying Nb film, the presence of the Nb film decreases the total resistivity (ρₜₒₜₐₗ) of the overlying Ru film by increasing the grain size (D) of the Ru film and/or by improving the crystalline orientation of the Ru film during the Ru deposition process. In some embodiments, a 1-10 nm Nb film formed beneath an Ru film in an Ru/Nb film stack may decrease the resistivity of the Ru film by approximately 10-15%, compared to the resistivity of an Ru film of the same thickness without an underlying Nb film. In one example embodiment, a 6 nm Nb film formed beneath a 30 nm Ru film may decrease the total resistivity of the 30 nm Ru film from about 11.5 μΩ cm to about 9.8 μΩ cm, as shown in FIG. 3. In addition to reducing film resistivity, the relatively thin Nb film included within the Ru/Nb film stack may provide the further benefit of reducing the Ru film thickness needed to achieve a low-resistivity interconnect structure. As Nb is comparatively cheaper than Ru, the reduction in Ru film thickness may reduce process cost. Other advantages not explicitly mentioned herein may be apparent to a skilled artisan having the benefit of this disclosure.

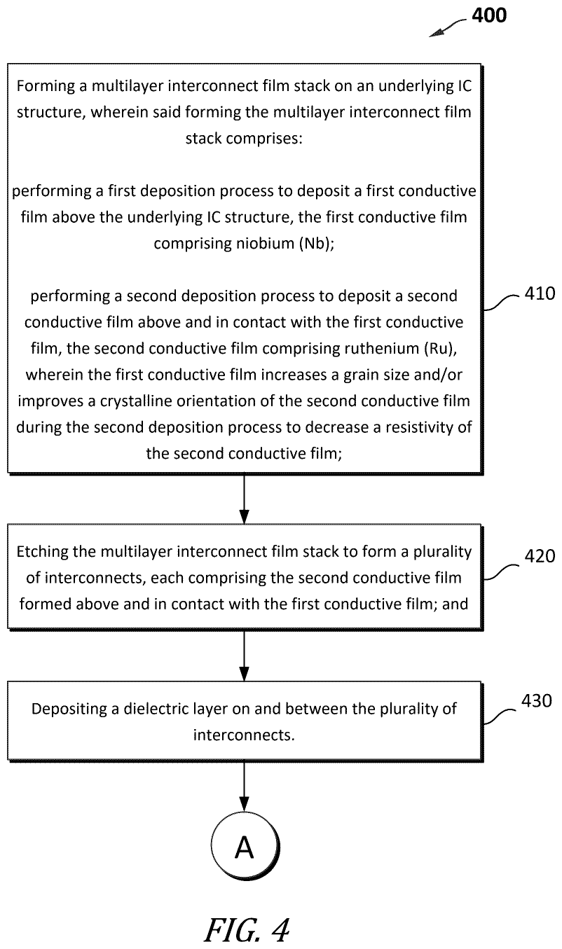

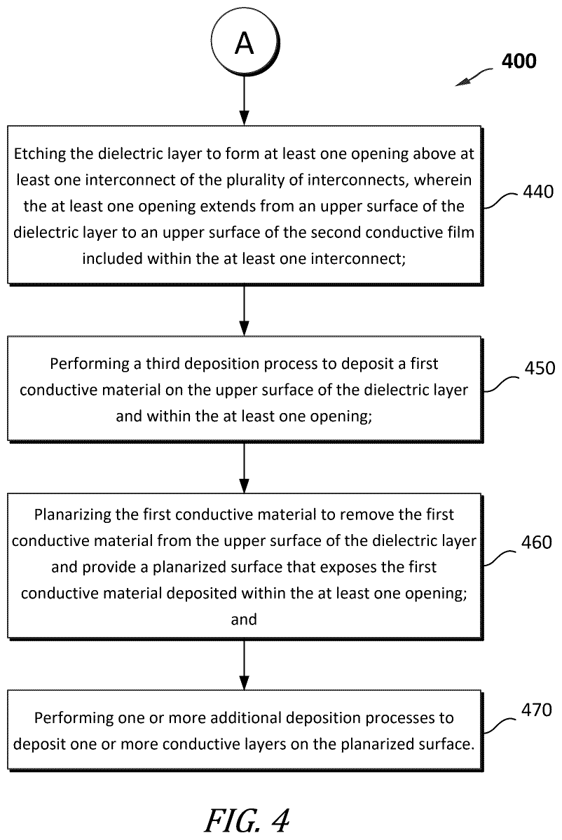

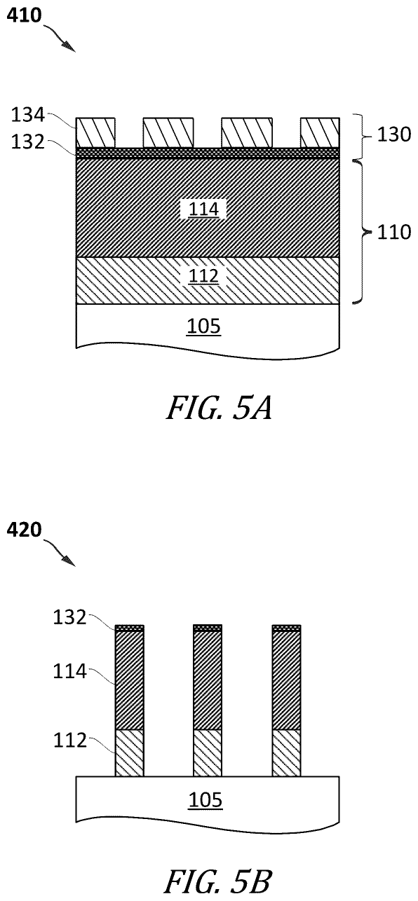

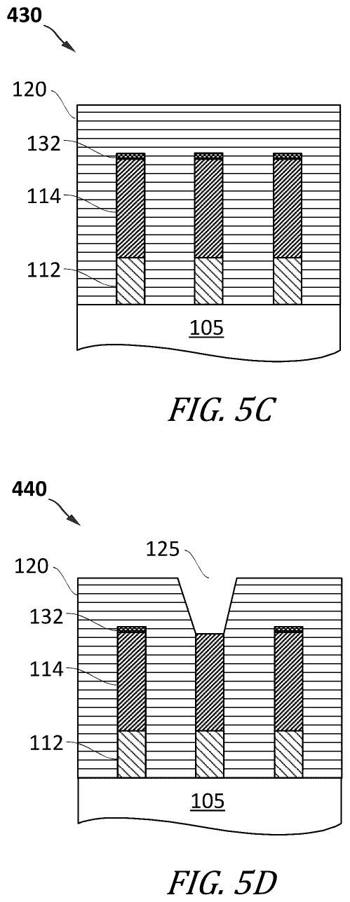

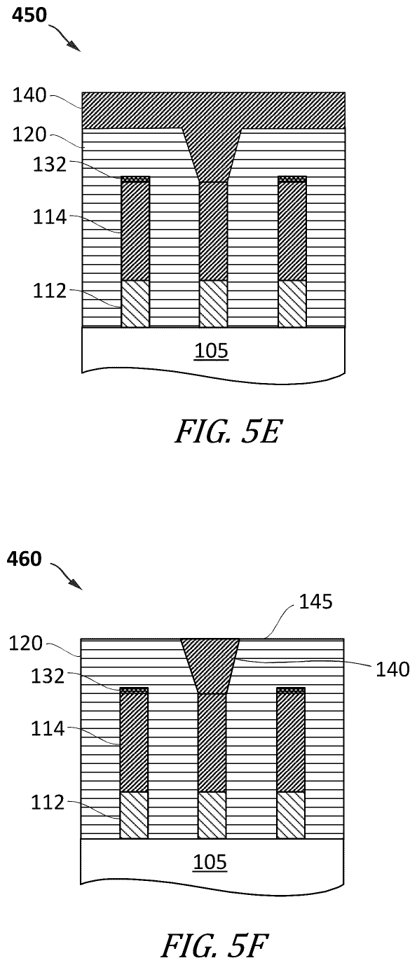

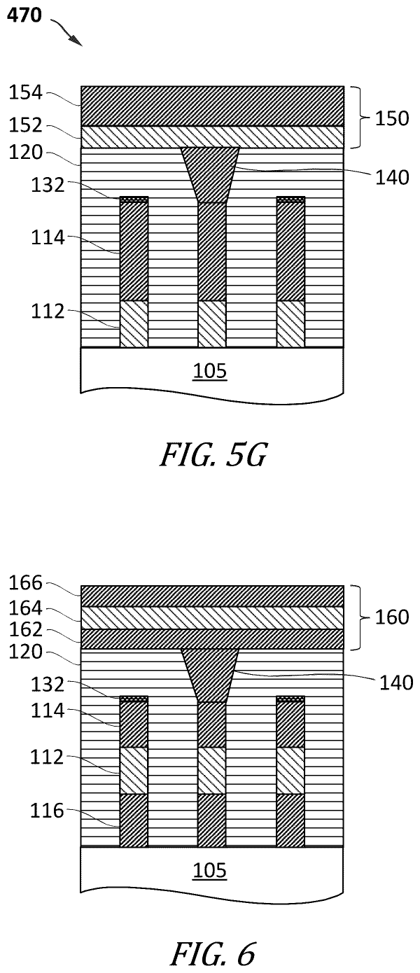

FIG. 4 illustrates one embodiment of a method 400 that utilizes the techniques described herein to form a low-resistivity interconnect structure. An example process flow that utilizes the method 400 is shown in FIGS. 5A-5G. A subtractive technique is used to form a low-resistivity interconnect structure in the method and process flow shown in FIGS. 4-5. It is recognized, however, that the method and process flow shown in FIGS. 4-5 are merely exemplary and additional methods and process flows may utilize the techniques disclosed herein to form a low-resistivity interconnect structures in accordance with the present disclosure. Further, additional processing steps may be added to the method 400 shown in FIG. 4 and/or the process flow shown in FIGS. 5A-5G, as the steps described therein are not intended to be exclusive. Moreover, the order of the steps is not limited to the order shown in the figures as different orders may occur and/or various steps may be performed in combination or at the same time.

As shown in FIG. 4 and FIG. 5A, the method 400 may generally begin by forming a multilayer interconnect film stack 110 on an underlying IC structure 105 (in step 410). The multilayer interconnect film stack 110 may be formed in step 410 by performing a first deposition process to deposit a first conductive film 112 above the underlying IC structure 105 and subsequently performing a second deposition process to deposit a second conductive film 114 above and in contact with the first conductive film 112. The first conductive film 112 may generally comprise niobium (Nb). For example, first conductive film 112 may be a niobium (Nb) film, a niobium oxide (NbₓO_{y}) film or a niobium nitride (NbN) film. The second conductive film 114 may generally comprise ruthenium (Ru). For example, second conductive film 114 may be a ruthenium (Ru) film, a ruthenium oxide (RuOₓ) film or a ruthenium nitride (RuNₓ) film. When the second conductive film 114 is deposited onto the first conductive film 112 during the second deposition process, the presence of the first conductive film 112 may increase a grain size and/or improve a crystalline orientation of the second conductive film 114 to decrease a resistivity of the overlying second conductive film 114.

A wide variety of deposition processes may be used to form the first conductive film 112 and the second conductive film 114 of the multilayer interconnect film stack 110. For example, the first deposition process used to deposit a first conductive film 112 and the second deposition process used to deposit the second conductive film 114 may be a physical vapor deposition (PVD) process, a chemical vapor deposition (CVD) process or an atomic layer deposition (ALD) process. In one example embodiment, the first conductive film 112 and the second conductive film 114 may each be deposited via PVD using suitable process gases and conditions. The process gases and conditions (e.g., temperature, pressure, etc.) may generally depend on the conductive films being formed. For example, when depositing a niobium (Nb) film via PVD, a niobium-containing gas mixture can be used, optionally in combination with one or more dilution gases (e.g., argon, krypton, etc.), at a variety of pressure (e.g., 0.1-10 mTorr), power (e.g., 100-1500 W), flow, and temperature conditions to generate a plasma used to form the Nb film. When depositing a ruthenium (Ru) film via PVD, a ruthenium-containing gas mixture can be used, optionally in combination with one or more dilution gases (e.g., argon, krypton, etc.), at a variety of pressure (e.g., 0.1-10 mTorr), power (e.g., 100-1500 W), flow, and temperature conditions to generate a plasma used to form the Ru film.

Once the multilayer interconnect film stack 110 is formed, a variety of overlying layers 130 may be formed on and above the multilayer interconnect film stack 110, such as the hard mask layer 132 and photoresist (PR) layer 134 shown in FIG. 5A. The overlying layers 130 may include additional layers, such as an antireflective coating (ARC) layer, as is known in the art. The hard mask layer 132 may include a wide variety hard mask materials, such as but not limited to, amorphous carbon, amorphous silicon (a-Si), polycrystalline silicon (poly-Si) or silicon dioxide (SiO₂). The PR layer 134 may include any photoresist used in 193 nm immersion technology, including positive tone and negative tone photoresist layers. After the overlying layers 130 are formed, the PR layer 134 may be patterned using lithography techniques to create a photoresist pattern as shown, for example, in FIG. 5A before etch process(es) are performed to transfer the photoresist pattern to the hard mask layer 132.

As shown in FIG. 4 and FIG. 5B, the method 400 may use the hard mask pattern to etch the multilayer interconnect film stack 110 to form a plurality of interconnects, each comprising the second conductive film 114 formed above and in contact with the first conductive film 112 (in step 420). A wide variety of etch processes and chemistries may be used to etch the conductive film layers included within the multilayer interconnect film stack 110. Examples of etch processes that may be used to etch the conductive film layers include, but are not limited to, reactive ion etching (RIE) and inductively coupled plasma (ICP) etching.

As shown in FIG. 4 and FIGS. 5C-5D, the method 400 may further include depositing a dielectric layer 120 on and between the plurality of interconnects (in step 430) and subsequently etching the dielectric layer 120 to form at least one opening 125 above at least one interconnect of the plurality of interconnects (in step 440). The dielectric layer 120 deposited in step 430 may include any suitable dielectric material, such as an interlayer dielectric (ILD) layer material or another low-k dielectric material. As shown in FIG. 5D, the at least one opening 125 formed within the dielectric layer 120 may extend from an upper surface of the dielectric layer 120 to an upper surface of the second conductive film 114 included within the at least one interconnect.

After the at least one opening 125 is formed within the dielectric layer 120, a third deposition process may be performed (in step 450) to deposit a first conductive material 140 on the upper surface of the dielectric layer 120 and within the at least one opening 125, as shown in FIG. 4 and FIG. 5E. A wide variety of deposition processes, such as CVD, PVD and ALD, may be used to deposit the first conductive material 140. In one example, a CVD process may be used to deposit the first conductive material 140 using suitable process gases and conditions. The process gases and conditions (e.g., temperature, pressure, etc.) may generally depend on the conductive material being formed.

Once the first conductive material 140 is deposited, the method 400 may planarize the first conductive material 140 to remove the first conductive material 140 from the upper surface of the dielectric layer 120 and provide a planarized surface 145 that exposes the first conductive material 140 deposited within the at least one opening 125 (in step 460), as shown in FIG. 4 and FIG. 5F. After planarization, one or more additional deposition processes may be performed to deposit one or more conductive layers 150 on the planarized surface 145 (in step 470), as shown in FIG. 4 and FIG. 5G. For example, the method 400 may perform a fourth deposition process to deposit a niobium (Nb) layer 152 on the planarized surface 145, and a fifth deposition process to deposit a ruthenium (Ru) layer 154 on the Nb layer (in step 470), as shown in FIG. 5G.

Similar to the Nb film discussed above, the Nb layer 152 formed beneath the Ru layer 154 may increase the grain size and improve the crystalline orientation of the Ru layer 154 formed during the fifth deposition process to decrease a resistivity of the Ru layer 154. In some embodiments, the deposition thickness of the Ru layer 154 may be greater than the deposition thickness of the Nb layer 152 to improve the overall conductivity of the interconnect structure. In one example embodiment, a 10-100 nm Ru layer 154 may be deposited on a 1-10 nm Nb layer 152 in step 470.

A wide variety of deposition processes, such as CVD, PVD and ALD, may be used to deposit the Nb layer 152 and the Ru layer 154. In one example, the Nb and Ru layers may each be PVD deposited using suitable process gases and conditions. The process gases and conditions (e.g., temperature, pressure, etc.) may generally depend on the material layer being formed. For example, when depositing a Nb layer 152 via PVD, a niobium-containing gas mixture can be used, optionally in combination with one or more dilution gases (e.g., argon, krypton, etc.), at a variety of pressure (e.g., 0.1-10 mTorr), power (e.g., 100-1500 W), flow, and temperature conditions to generate a plasma used to form the Nb film. When depositing a Ru layer 154 via PVD, a ruthenium-containing gas mixture can be used, optionally in combination with one or more dilution gases (e.g., argon, krypton, etc.), at a variety of pressure (e.g., 0.1-10 mTorr), power (e.g., 100-1500 W), flow, and temperature conditions to generate a plasma used to form the Ru film.

FIG. 6 is a cross-sectional view of a portion of an IC device illustrating another embodiment of a low-resistivity interconnect structure formed in accordance with the present disclosure. A method and process flow similar to what is shown in FIGS. 4-5 may be used to form the low-resistivity interconnect structure shown in FIG. 6 with a few key differences. Unlike the previous embodiment shown in FIGS. 4-5, the low-resistivity interconnect structure shown in FIG. 6 may use a variety of deposition processes (e.g., CVD, PVD, ALD, etc.) and deposition steps to form a multilayer interconnect film stack 110 as shown in FIG. 1B. For example, a third conductive film 116 (e.g., a “second” ruthenium film) may be deposited onto the underlying IC structure 105 via a PVD process before performing additional PVD processes to successively deposit the first conductive film 112 (e.g., a niobium (Nb) film) on the third conductive film 116 and the second conductive film 114 (e.g., a ruthenium film) on the first conductive film 112.

After forming a multilayer interconnect film stack 110 comprising a third conductive film 116, a first conductive film 112 and a second conductive film 114, the overlying layers 130 may be formed and patterned, as discussed above in reference to FIG. 4 and FIG. 5A. Thereafter, the multilayer interconnect film stack 110 may be etched to form a plurality of interconnects before depositing a dielectric layer 120 on and between the plurality of interconnects, and etching the dielectric layer 120 to form at least one opening 125 above at least one interconnect of the plurality of interconnects, as shown in FIG. 4 and FIGS. 5B-5D. Thereafter, the method and process flow may deposit a first conductive material 140 on the upper surface of the dielectric layer 120 and within the at least one opening 125 before planarizing the first conductive material 140 to provide a planarized surface 145, as discussed above and shown in FIG. 4 and FIGS. 5E-5F.

Like the previous embodiment shown in FIG. 5G, additional deposition processes may be performed to deposit additional conductive layers 160 on the planarized surface 145. In the embodiment shown in FIG. 6, a fourth deposition process is performed to deposit a first Ru layer 162 on the planarized surface 145, a fifth deposition process is performed to deposit an Nb layer 164 on the first Ru layer 162, and a sixth deposition process is performed to deposit a second Ru layer 166 on the Nb layer 164. In one example embodiment, a 20-50 nm first Ru layer 162 may be deposited on the planarized surface 145 followed by a 1-10 nm Nb layer 164 and a 20-50 nm second Ru layer 166. Similar to the embodiment discussed above, the Nb layer 164 formed beneath the second Ru layer 166 may increase the grain size and improve the crystalline orientation of the second Ru layer 166 formed during the sixth deposition process to decrease a resistivity of the second Ru layer 166.

Techniques for forming low-resistivity interconnect structures used within an IC device formed on a semiconductor substrate are described in various embodiments. The term “semiconductor substrate” or “substrate” as used herein means and includes a base material or construction upon which materials are formed. It will be appreciated that the substrate may include a single material, a plurality of layers of different materials, a layer or layers having regions of different materials or different structures in them, etc. These materials may include semiconductors, insulators, conductors, or combinations thereof. For example, the substrate may be a semiconductor substrate, a base semiconductor layer on a supporting structure, a metal electrode or a semiconductor substrate having one or more layers, structures or regions formed thereon. The substrate may be a conventional silicon substrate or other bulk substrate comprising a layer of semi-conductive material. As used herein, the term “bulk substrate” means and includes not only silicon wafers, but also silicon-on-insulator (“SOI”) substrates, such as silicon-on-sapphire (“SOS”) substrates and silicon-on-glass (“SOG”) substrates, epitaxial layers of silicon on a base semiconductor foundation, and other semiconductor or optoelectronic materials, such as silicon-germanium, germanium, gallium arsenide, gallium nitride, and indium phosphide. The substrate may be doped or undoped.

The substrate may also include any material portion or structure of a device, particularly a semiconductor or other electronics device, and may, for example, be a base substrate structure, such as a semiconductor substrate or a layer on or overlying a base substrate structure. Thus, the term “substrate” is not intended to be limited to any particular base structure, underlying layer or overlying layer, patterned layer or unpatterned layer, but rather, is contemplated to include any such layer or base structure, and any combination of layers and/or base structures.

It is noted that reference throughout this specification to “one embodiment” or “an embodiment” means that a particular feature, structure, material, or characteristic described in connection with the embodiment is included in at least one embodiment of the invention, but do not denote that they are present in every embodiment. Thus, the appearances of the phrases “in one embodiment” or “in an embodiment” in various places throughout this specification are not necessarily referring to the same embodiment of the invention. Furthermore, the particular features, structures, materials, or characteristics may be combined in any suitable manner in one or more embodiments. Various additional layers and/or structures may be included and/or described features may be omitted in other embodiments.

One skilled in the relevant art will recognize that the various embodiments may be practiced without one or more of the specific details, or with other replacement and/or additional methods, materials, or components. In other instances, well-known structures, materials, or operations are not shown or described in detail to avoid obscuring aspects of various embodiments of the invention. Similarly, for purposes of explanation, specific numbers, materials, and configurations are set forth in order to provide a thorough understanding of the invention. Nevertheless, the invention may be practiced without specific details. Furthermore, it is understood that the various embodiments shown in the figures are illustrative representations and are not necessarily drawn to scale.

Further modifications and alternative embodiments of the methods described herein will be apparent to those skilled in the art in view of this description. It will be recognized, therefore, that the described methods are not limited by these example arrangements. It is to be understood that the forms of the methods herein shown and described are to be taken as example embodiments. Various changes may be made in the implementations. Thus, although the inventions are described herein with reference to specific embodiments, various modifications and changes can be made without departing from the scope of the present inventions. Accordingly, the specification and figures are to be regarded in an illustrative rather than a restrictive sense, and such modifications are intended to be included within the scope of the present inventions. Further, any benefits, advantages, or solutions to problems that are described herein with regard to specific embodiments are not intended to be construed as a critical, required, or essential feature or element of any or all the claims.

What is claimed is:

1. An integrated circuit (IC) device comprising at least one interconnect, the at least one interconnect comprising:
a multilayer interconnect film stack comprising a first conductive film formed beneath and in contact with a second conductive film, wherein the first conductive film comprises niobium (Nb), wherein the second conductive film comprises ruthenium (Ru), and wherein the first conductive film decreases a resistivity of the second conductive film by increasing a grain size and/or improving a crystalline orientation of the second conductive film.

2. The IC device of claim 1, wherein the first conductive film increases the grain size and/or improves the crystalline orientation of the second conductive film during a deposition process used to deposit the second conductive film onto the first conductive film to form the multilayer interconnect film stack.

3. The IC device of claim 1, wherein the first conductive film is a niobium (Nb) film, a niobium oxide (NbₓO_{y}) film or a niobium nitride (NbN) film, and wherein the second conductive film is a ruthenium (Ru) film, a ruthenium oxide (RuOₓ) film or a ruthenium nitride (RuNₓ) film.

4. The IC device of claim 1, wherein the first conductive film is a niobium (Nb) film and the second conductive film is a ruthenium (Ru) film.

5. The IC device of claim 4, wherein the niobium (Nb) film decreases a resistivity of the ruthenium (Ru) film by approximately 10-15% compared to a resistivity of a ruthenium (Ru) film of the same thickness without an underlying niobium (Nb) film.

6. The IC device of claim 4, wherein a thickness of the ruthenium (Ru) film ranges between 20 nm and 100 nm.

7. The IC device of claim 6, wherein a thickness of the niobium (Nb) film ranges between 1 nm and 10 nm.

8. The IC device of claim 6, wherein the thickness of the ruthenium (Ru) film ranges between 25 nm and 45 nm, wherein the thickness of the niobium (Nb) film ranges between 3 nm and 6 nm.

9. The IC device of claim 4, wherein the multilayer interconnect film stack further comprises a second ruthenium (Ru) film formed below and in contact with the niobium (Nb) film, wherein a thickness of the ruthenium (Ru) film ranges between 5 nm and 50 nm, wherein the thickness of the niobium (Nb) film ranges between 1 nm and 10 nm, and wherein a thickness of the second ruthenium (Ru) film ranges between 5 nm and 50 nm.

10. A method of forming interconnects in an integrated circuit (IC) device, the method comprising:
forming a multilayer interconnect film stack on an underlying IC structure, wherein said forming the multilayer interconnect film stack comprises:
performing a first deposition process to deposit a first conductive film above the underlying IC structure, the first conductive film comprising niobium (Nb);
performing a second deposition process to deposit a second conductive film above and in contact with the first conductive film, the second conductive film comprising ruthenium (Ru), wherein the first conductive film increases a grain size and/or improves a crystalline orientation of the second conductive film during the second deposition process to decrease a resistivity of the second conductive film;
etching the multilayer interconnect film stack to form a plurality of interconnects, each comprising the second conductive film formed above and in contact with the first conductive film; and
depositing a dielectric layer on and between the plurality of interconnects.

11. The method of claim 10, wherein the first conductive film is a niobium (Nb) film, a niobium oxide (NbₓO_{y}) film or a niobium nitride (NbN) film, and wherein the second conductive film is a ruthenium (Ru) film, a ruthenium oxide (RuOₓ) film or a ruthenium nitride (RuNₓ) film.

12. The method of claim 10, wherein the first conductive film is a niobium (Nb) film and the second conductive film is a ruthenium (Ru) film.

13. The method of claim 12, wherein the niobium (Nb) film decreases a resistivity of the ruthenium (Ru) film by approximately 10-15% compared to a resistivity of a ruthenium (Ru) film of the same thickness without an underlying niobium (Nb) film.

14. The method of claim 12, wherein a thickness of the ruthenium (Ru) film ranges between 20 nm and 100 nm, and wherein a thickness of the niobium (Nb) film ranges between 1 nm and 10 nm.

15. The method of claim 12, wherein said forming the multilayer interconnect film stack further comprises:
performing a deposition process to deposit a second ruthenium (Ru) film on the underlying IC structure before the first deposition process is performed to deposit the niobium (Nb) film on the second ruthenium (Ru) film;
wherein a thickness of the ruthenium (Ru) film ranges between 5 nm and 50 nm;
wherein the thickness of the niobium (Nb) film ranges between 1 nm and 10 nm; and
wherein a thickness of the second ruthenium (Ru) film ranges between 5 nm and 50 nm.

16. The method of claim 10, further comprising:
etching the dielectric layer to form at least one opening above at least one interconnect of the plurality of interconnects, wherein the at least one opening extends from an upper surface of the dielectric layer to an upper surface of the second conductive film included within the at least one interconnect;
performing a third deposition process to deposit a first conductive material on the upper surface of the dielectric layer and within the at least one opening;
planarizing the first conductive material to remove the first conductive material from the upper surface of the dielectric layer and provide a planarized surface that exposes the first conductive material deposited within the at least one opening; and
performing one or more additional deposition processes to deposit one or more conductive layers on the planarized surface.

17. The method of claim 16, further comprising:
performing a fourth deposition process to deposit a niobium (Nb) layer on the planarized surface; and
performing a fifth deposition process to deposit a ruthenium (Ru) layer on the niobium (Nb) layer, wherein the niobium (Nb) layer increases a grain size and improves a crystalline orientation of the ruthenium (Ru) layer during the fifth deposition process to decrease a resistivity of the ruthenium (Ru) layer.

18. The method of claim 17, wherein a thickness of the niobium (Nb) layer ranges between 1 nm and 10 nm, and wherein a thickness of the ruthenium (Ru) layer ranges between 10 nm and 100 nm.

19. The method of claim 16, further comprising:
performing a fourth deposition process to deposit a first ruthenium (Ru) layer on the planarized surface;
performing a fifth deposition process to deposit a niobium (Nb) layer on the first ruthenium (Ru) layer; and
performing a sixth deposition process to deposit a second ruthenium (Ru) layer on the niobium (Nb) layer, wherein the niobium (Nb) layer increases a grain size and improves a crystalline orientation of the second ruthenium (Ru) layer during the sixth deposition process to decrease a resistivity of the second ruthenium (Ru) layer.

20. The method of claim 19, wherein a thickness of the first ruthenium (Ru) layer ranges between 20 nm and 50 nm, wherein a thickness of the niobium (Nb) layer ranges between 1 nm and 10 nm, and wherein a thickness of the second ruthenium (Ru) layer ranges between 20 nm and 50 nm.
